(19) United States
(12) Patent Application Publication
(10) Pub. No.: US 2017/0220506 A1
(43) Pub. Date: Aug. 3, 2017

(54) Modular Software Defined Storage Technology

(71) Applicant: Dedicated Computing, LLC, Waukesha, WI (US)

(72) Inventors: Wade Brown, Waukesha, WI (US); Brandon Feil, Brookfield, WI (US); Jeff Krueger, Hartland, WI (US); Phillip Spindler, Hartland, WI (US); Brad Wadsworth, Pewaukee, WI (US)

(21) Appl. No.: 15/010,547

(22) Filed: Jan. 29, 2016

(51) Int. Cl. G06F 13/40; G06F 13/38; G06F 13/42; H05K 7/14; G06F 9/44

(52) U.S. Cl. CPC G06F 13/4068; H05K 7/1488; G06F 9/4401; G06F 13/4022; G06F 13/4282; G06F 13/387

(57) ABSTRACT

A modular software-defined storage system and method for providing modular software-defined storage, and components thereof, are disclosed herein. In at least one example embodiment, the storage system includes a backplane, a plurality of storage pods, and a management module storing at least one computer program for causing the storage pods to be configured for operation and for facilitating, when the storage pods are configured for operation, storage of information on the storage pods in accordance with a software-defined storage application. The system also includes first and second interfaces by which an additional computer device can at least indirectly engage in communications with the storage system and by which the storage system can at least indirectly engage in additional communications with an additional system having at least one additional storage pod such that the storage system is expanded to allow for additional storage.

### CROSS-REFERENCE TO RELATED APPLICATIONS

### STATEMENT REGARDING FEDERALLY SPONSORED RESEARCH OR DEVELOPMENT

### FIELD OF THE INVENTION

The present invention relates to systems and methods for storing information and, more particularly to systems and methods for storing information by way of software-defined storage.

### BACKGROUND OF THE INVENTION

A variety of types of computer memory or information storage systems have been developed over the years. One conventional manner of storing information is by storing the information in the form of files and block storage. For example, in a computer, data or files can be stored to a hard drive (disk drive), and the operating system in conjunction with the disk drive stores all appropriate information as blocks and files that is, on the storage media, information is stored as blocks and those blocks are seen by the operating system as files.

Numerous storage advances have been made over the last twenty years to increase storage size, performance, redundancy, and management capability above and beyond basic file/block storage, including Direct Attached Storage (DAS), Redundant Array of Independent (or Inexpensive) Disks (RAID), Just a Bunch of Disks (JBOD), Network Attached Storage (NAS), and Storage Area Network (SAN) systems. It should be appreciated that, particularly when dealing with present-day network-based storage systems, certain systems or subsystems can be made available to users as block devices that leave file system concerns to the client—for example, SAS (Serial Attached SCSI, with SCSI referring to a Small Computer System Interface) systems. Alternatively, in other cases, network-based storage is made available at the file-level—for example, in the case of NAS systems.

Although the aforementioned technologies can be advantageous in various respects relative to basic file/block storage on a disk drive, each of these technologies has one or more disadvantages. More particularly, DAS systems suffer from a lack of redundancy (which can result in or risk data loss) and a limited ability to grow beyond a certain point (extremely limited when considering competing storage (subsystems). Typically, DAS systems are not shared to facilitate network-based file storage. As for RAID and JBOD systems, although these systems can be used to create larger disk storage space than that provided by a single drive, RAID systems are still limited in terms of overall storage size and capability, and JBOD systems are lacking in terms of redundancy. Additionally, with respect to both NAS-based storage and SAN-based storage, since such arrangements do not employ dedicated high-speed communication links (busses), this can result in limitations on bandwidth. Further, NAS storage is somewhat limited in its overall storage capability, speed, maintenance, and ability to grow without significant user intervention.

In recent years, there have further been developed additional storage technologies that particularly serve to abstract software functionality from hardware. One such additional storage technology can be referred to as object storage, and involves systems that are designed to operate by treating data as objects, in contrast with storage architectures involving file/block storage. Systems employing another related technology, which can be referred to as software-defined storage, are configured to operate by separating data request and the physical storage components so as to enable pooling, replication, and storage diversification and thereby provide aggregated, flexible, efficient, and scalable storage systems or subsystems.

Although object storage systems and software-defined storage systems are widely used, such systems have certain limitations. In particular, current software-defined storage systems are geared toward large-scale enterprise applications such as large data centers. This has led to the hardware in such systems being large-scale server/workstation class hardware including, for example, racks of computers. Installing such a large-scale system entails significant upfront costs for purchasing the base hardware platform because typically it is desired that the system possess enough computing power to be able to service all of the hard drives that the platform could ever support. In addition, an expensive high-end communications infrastructure is typically required to provide interconnects between components at speeds that are high enough to support the number of hard drives in an individual enclosure.

Further, conventional software-defined storage systems are typically built using common-off-the-shelf server hardware. That hardware and associated infrastructure is typically over-provisioned and not always compute balanced in terms of aligning the needs of the network, central processing unit (CPU), and disk storage in terms of software-defined storage needs. Thermals, space, and cost are not optimized for many such conventional software-based storage systems utilizing a server hardware based approach. Indeed, in such systems, excessive power is often consumed as a result of the use of thermal management techniques appropriate for cooling large CPUs, and significant space is often wasted due to the use of large motherboards that occupy space that is largely not used.

Therefore, for the above reasons, it would be advantageous if an improved storage system and/or method for storing information could be developed that addressed one or more of the limitations associated with one or more conventional storage systems and methods such as (but not limited to) those described above, and/or provided one or more enhancements or advantages relative to one or more conventional storage systems and methods such as (but not limited to) those described above.

### BRIEF SUMMARY OF THE INVENTION

In at least some embodiments encompassed herein, the present invention relates to a modular software-defined storage system. The system includes a backplane, and a plurality of first storage pods each configured to be at least indirectly coupled to the backplane, where each of the first storage pods includes a respective memory component and a respective processing component. The system also includes a management module coupled to the backplane, where the management module includes a non-transitory computer readable storage medium storing at least one computer program for causing the first storage pods to be configured for operation and for facilitating, when the first storage pods are configured for operation, first storage of first information on the first storage pods in accordance with a software-defined storage application. Further, the system includes a first interface coupled at least indirectly with the backplane or the management module by which an additional computer device can at least indirectly engage in communications with the storage system in a manner resulting in the first storage of the first information on the first storage pods. Additionally, the system includes a second interface coupled at least indirectly with the backplane or the management module by which the storage system can at least indirectly engage in additional communications with an additional system having at least one additional storage pod such that the storage system is expanded to allow for additional storage of additional information on the at least one additional storage pod.

Additionally, in at least some embodiments, the present invention relates to a storage pod for use as part of a modular software-defined storage system. The storage pod has a memory device including one or more of a hard drive, a solid state disk, a random access memory (RAM) device, and a Flash memory device, and a processing device coupled to the memory device, the processing device including one or more of a CPU component and a SOC component. The storage pod also includes a first port coupled at least indirectly to the processing device by which the storage pod can be electrically coupled to a backplane of the modular software-defined storage system. The processing device includes a non-transitory computer readable storage medium configured to be capable of storing at least one computer program for allowing the storage pod to receive and store first information at the memory device in accordance with a software-defined storage application. Additionally, the storage pod is configured to engage in communications with the backplane by way of the first port and also to receive power from the backplane by way of the first port.

Further, in least some embodiments, the present invention relates to a method for providing modular software-defined storage. The method includes providing a main structure having a backplane and a management module, and receiving at the backplane a first storage pod so that the first storage pod is electrically coupled to the backplane, where the first storage pod includes both a memory device and a processing device. The method also includes sending, from the processing device of the first storage pod to the management module, first information regarding a first characteristic of the first storage pod. The method further includes communicating, from the management module to the processing device of the first storage pod, at least some second information so as to achieve configuration of the first storage pod for operation as part of a storage system including the first storage pod and the main structure, where the second information includes at least some computer programming configured to allow the storage pod to receive and store third information at the memory device of the first storage pod in accordance with a software-defined storage application. Additionally, the method also includes operating the management module, the backplane, and the first storage pod as a storage system so that the third information is stored at the memory device of the first storage pod as governed by the management module in accordance with the software-defined storage application.

### BRIEF DESCRIPTION OF THE DRAWINGS

FIG. 1 is a top perspective view of a storage appliance employing a main structure and a plurality of storage pods, which constitutes an example system for modular software-defined storage in accordance with one embodiment encompassed herein;

FIG. 2 is a front elevation view of a first one of the storage pods shown in FIG. 1 that illustrates example components provided therewithin;

FIG. 3A is a top perspective view of an additional storage pod that is an alternative embodiment of a storage pod by comparison with the storage pods shown in FIGS. 1 and 2, and that can be utilized in connection with the main structure of FIG. 1 in place of any one or more of the storage pods shown in FIGS. 1 and 2;

FIG. 3B is a bottom perspective view of example internal components of the storage pod of FIG. 3A, that is, a bottom perspective view of the storage pod with a carrier portion of the storage pod absent;

FIG. 4A is an image providing a top perspective view of an example circuit board that can be implemented in the storage pod of FIGS. 3A and 3B;

FIG. 4B is an image providing a bottom perspective view of an example hard drive with the circuit board of FIG. 4A mounted thereon;

FIG. 4C is an image providing a bottom perspective view of an example storage pod that can correspond to that of FIGS. 3A and 3B, that can be implemented to include the hard drive and circuit board of FIGS. 4A and 4B, and that includes a door section shown in an open position;

FIG. 5 is a block diagram illustrating example processing or related components of an overall processor or processing system that can be employed in a storage pod such as any of those of FIGS. 1-4C for the purpose of providing or implementing object storage processing or software-defined storage, shown in relation to a physical storage device of the storage pod and other example components of a storage appliance such as that of FIG. 1 in relation to which the storage pod is implanted;

FIG. 6 is a block diagram illustrating example processing or related components of an alternate embodiment of an overall processor or processing system that differs from that of FIG. 5 and that can be employed in a storage pod such as any of those of FIGS. 1-4C for the purpose of providing or implementing object storage processing or software-defined storage, shown in relation to a physical storage device of the storage pod and other example components of a storage appliance such as that of FIG. 1 in relation to which the storage pod is implanted;

FIG. 7 is a schematic diagram illustrating example functional blocks (or functional components or modules) of a storage appliance such as the storage appliance shown in FIG. 1, which can employ any of the storage pods and associated components of FIGS. 1-6, in accordance with at least some embodiments encompassed herein;

FIG. 8 is a schematic diagram illustrating example functional blocks (or functional components or modules) of a storage pod that can be employed as any of the storage pods shown in or described in relation to FIGS. 1-7, in accordance with at least some embodiments encompassed herein;

FIG. 9 is a schematic diagram illustrating example functional blocks (or functional components or modules) of an alternate embodiment of a storage pod, which differs from that of FIG. 8, and which can be employed as any of the storage pods shown in or described in relation to FIGS. 1-7, in accordance with at least some embodiments encompassed herein; and

FIG. 10 is a flow chart illustrating an example manner of operation of portions of a storage appliance such as any of those described in relation to FIGS. 1-9.

### DETAILED DESCRIPTION OF THE PREFERRED EMBODIMENT

The present disclosure is intended to encompass a variety of embodiments of systems and methods for modular software-defined storage. At least some such embodiments are systems that employ one or more information storage pods (which can also be referred to as storage modules, cartridges, elements, or blades) that fit into an overall storage appliance. In at least some such embodiments, the storage pods are configured to minimize ancillary components of object storage processing or software-defined storage. To facilitate the minimization of non-necessary components, the storage pods are configured to receive power and networking from a separate discrete source. Additionally, in at least some such embodiments, the storage pods particularly acquire power and networking from a backplane that aids in assembling multiple storage pods into a storage pool (or singular storage pools). Further, in at least some embodiments, the storage appliance facilitates the clustering of storage pods, and the chassis and backplane of the storage appliance provide cooling, power, networking, and software boot and control capabilities.

In at least some embodiments encompassed herein, the storage appliances overall can be considered as being a form of, or generally as fitting the concept of, microservers. However, the storage appliances disclosed herein differ from conventional microserver arrangements in that the storage appliances disclosed herein are purpose-specific, and particularly directed toward providing memory storage rather than processing.

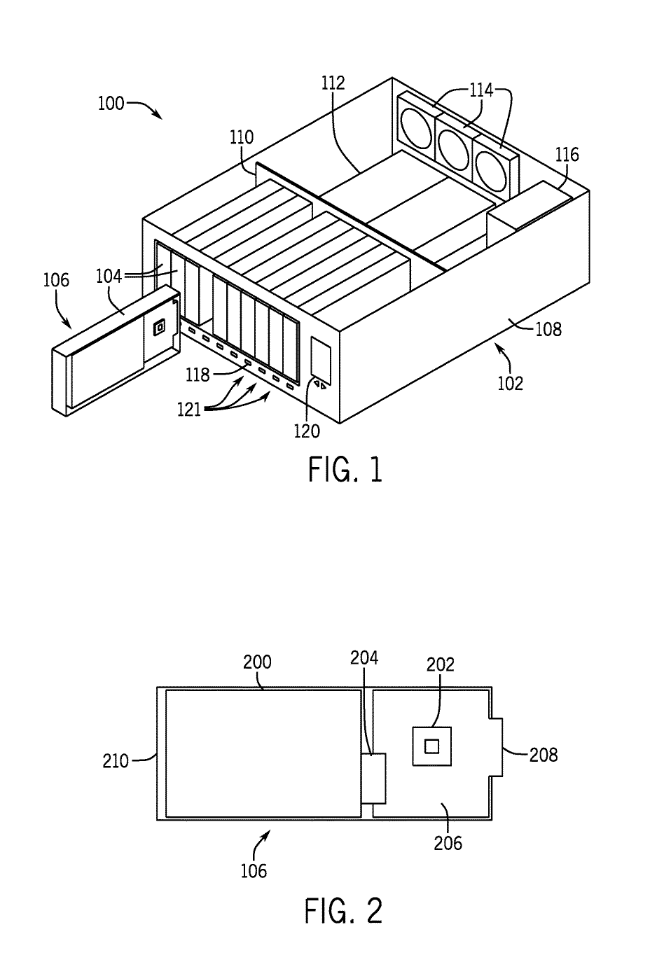

Referring to FIG. 1, a top perspective view of a storage appliance 100 employing a main structure 102 and multiple storage pods 104 is provided. The storage appliance 100 constitutes an example system for modular software-defined storage in accordance with one embodiment encompassed herein. A first one 106 of the multiple storage pods 104 is shown to be removed from the remainder of the storage appliance 100 so as to provide a top perspective view of that first one of the storage pods. As will be described further, below, each of the storage pods 104 includes an embedded computer (compute or processing capability) and storage device (memory device or component) in a singular container. Additionally, the storage appliance 100 includes a housing 108 that forms the support structure of the storage appliance, into which the multiple storage pods 104 can be positioned.

Further as shown, in addition to the multiple storage pods 104, the storage appliance 100 also includes a backplane 110, a compute pod or management module 112, multiple fans 114, and a power supply 116. It should be appreciated that, when each of the multiple storage pods 104 is inserted into the main structure 102, each storage pod particularly is inserted so as to contact, interface, and be connected to and in electrical communication with the backplane 110. Additionally, the backplane 110 also is connected to and in electrical communication with the management module 112. Further, the fans 114 are electrically in communication with, and receive power from, the power supply 116, and the power supply 116 also is either directly or indirectly connected with each of the management module 112 and backplane 110, as well as (indirectly via the backplane and possibly also the compute pod) connected with the multiple storage pods 104 when those storage pods are electrically coupled to the backplane.

Additionally as shown, in the present embodiment, the main structure 102 also includes multiple status indicators 118 and a status display 120. The respective status indicators 118 are respectively aligned with (respectively positioned beneath) respective locations at which the respective storage pods 104 can be inserted into the main structure 102. Each of the respective status indicators 118 is configured to provide a respective indication (e.g., configured to light up or change color) when a corresponding one of the storage pods 104 is inserted into the main structure 102 and in electrical communication with (e.g., plugged into) the backplane 110. Depending upon the embodiment, the respective status indicators 118 can also provide additional indications to indicate respective operational status or health characteristics of the respective storage pods 104 as discussed further below. For example, a given one of the status indicators 118 can switch color from red to green when a respective one of the storage pods 104 that is aligned with the status indicator becomes operational and capable of storing information.

The status display 120 can, depending upon the embodiment or implementation, provide any of a variety of indications of any of a variety of operational characteristics of the storage appliance 100. In at least some embodiments, the status display 120 can take the form of a touch screen and allow both for operator inputs as well as display outputs for viewing by an operator. Also, in at least some embodiments, the status display 120 can display information such as, for example, the proportion (e.g., percent usage) of the total memory afforded by the storage appliance 100, and/or can also display error information in the event any errors in operation have occurred with any of the storage pods 104 or other portions of the storage appliance.

In the present example embodiment, each of the storage pods 104 has structural features that are identical to those of the first one 106 of the storage pods, and each of the storage pods is configured to fit within a limited number of identically-sized and configured (or substantially identically-sized and configured) slots 121 of the housing 108. The features of the first one 106 of the storage pods 104 are shown more particularly in FIG. 2, which provides a front elevation view of the first one 106 of the storage pods 104. More particularly as shown, the first one 106 of the storage pods 104 (and thus each of the storage pods 104) includes a hard drive (e.g., a disk drive, HDD, SSD, etc.) 200 and an embedded computer 202 that typically is a small computer (e.g., ˜50 mm×˜80 mm). In at least some embodiments, the hard drive 200 can be or include an inexpensive hard drive such as a 3 ½ inch hard drive or a two to four Terabyte hard drive, and embedded computer 202 can be or include an Atom™ processor available from Intel Corporation of Santa Clara, Calif.

Additionally, the hard drive 200 includes a hard drive connection (or connector, port, or terminal) 204 by which the hard drive can be connected to (e.g., plugged into) and electrically in communication with an electrical circuit board 206 on which the embedded computer 202 is supported, such that the hard drive can be connected to and electrically in communication with the embedded computer. Although not shown, it should be appreciated that the electrical circuit board 206 has a receiving port that receives the hard drive connection 204 and permits the embedded computer 202 to be connected to and electrically in communication with the hard drive 200.

Further, the electrical circuit board 206 also includes a backplane connection (or connector, port, or terminal) 208 by which the electrical circuit board 206 and the embedded computer 202 thereon can be connected to (e.g., plugged into) and electrically in communication with the backplane 110 of the main structure 102 when the first one 106 of the storage pods 104 is inserted into the main structure. In at least some embodiments, the backplane connection 208 can be an Ethernet plug. Additionally, the first one 106 of the storage pods 104 also includes an external housing or carrier (or container) 210, into which the hard drive 200 and embedded computer 202 are positioned and supported. The carrier 210 serves to encase or protect the hard drive 200 and embedded computer 202 from the outside environment when the first one 106 of the storage pods 104 is removed from the main structure 102.

Although in the present embodiment all of the storage pods 104 have identical structural features, in other embodiments this need not be the case, and different ones of the storage pods can vary from one another in any of a variety of respects. For example, in some alternate embodiments, different ones of the storage pods can have different internal components (e.g., different memory components providing different amounts of storage capacity or different computing or processing components). Also for example, in some alternate embodiments, the external size or shape or other structural characteristics of one or more of the storage pods can differ from those of one or more others of the storage pods (e.g., one storage pod could have a physical width that was double that of another storage pod, such that the one storage pod occupied double the amount of space within the storage appliance when inserted therewithin than was occupied by the other storage pod).

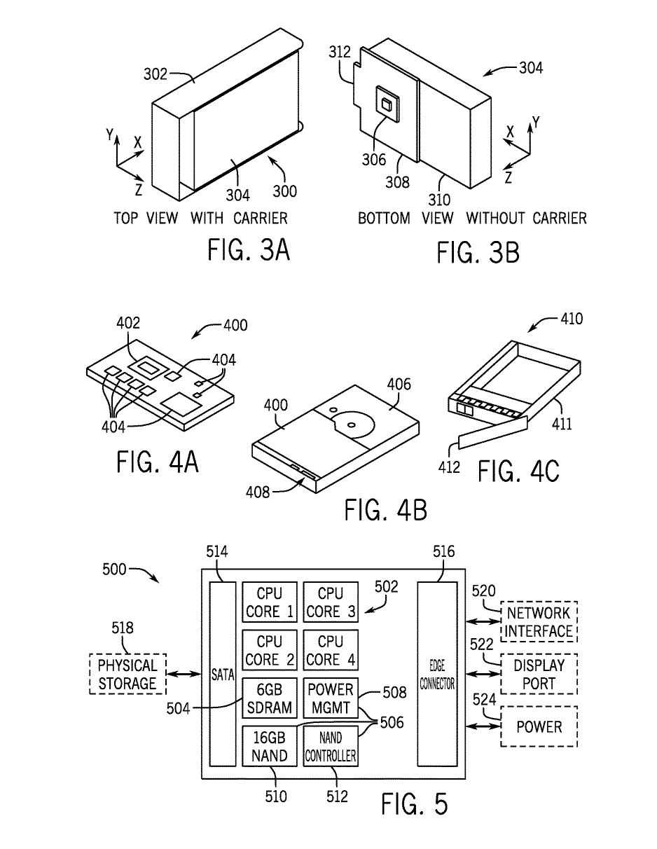

Turning to FIG. 3A, a top perspective view is provided of one example of an alternate embodiment of a storage pod 300. The storage pod 300 differs from the storage pods 104, 106 shown in FIGS. 1 and 2, but nevertheless can still be utilized in connection with the main structure 102 of the storage appliance 100 of FIG. 1 in place of any one or more of the storage pods 104. FIG. 3A particularly shows an external housing or carrier 302 of the storage pod 300 and an internal component portion 304. To further illustrate the internal component portion 304, FIG. 3B is additionally provided. More particularly, FIG. 3B is a bottom perspective view of the internal component portion 304 and particularly shows that the internal component portion includes an embedded computer 306 mounted on an electrical circuit board 308 that is mounted on a hard drive (disk drive) 310. It should be appreciated that the hard drive 310 and electrical circuit board 308 are directly connected and in electrical communication with one another, and therefore that the hard drive 310 and the embedded computer 306 are at least indirectly connected and in electrical communication with one another.

Additionally, the electrical circuit board 308 further includes a backplane connection (or connector, port, or terminal) 312 by which the electrical circuit board 308 and the embedded computer 306 thereon can be connected to (e.g., plugged into) and electrically in communication with the backplane 110 of the main structure 102 when the storage pod 300 is inserted into the main structure. It also should be appreciated that the carrier 302 shown in FIG. 3A serves to encase or protect the internal component portion 304 (including the hard drive 310 and electrical circuit board 308 with the embedded computer 306) from the external environment. Given this configuration, it should additionally be appreciated that the storage pod 300 is configured in a manner such that the computer (compute/processing) portion of the storage pod is stacked with the hard drive, with the computer being placed between the carrier and hard drive (although alternate configurations are also possible and intended to be encompassed herein).

Referring additionally to FIGS. 4A, 4B, and 4C, additional images are provided to show in further detail how a storage pod having a computer portion being stacked with a hard drive, such as the storage pod 300 of FIGS. 3A and 3B, can appear in practice. FIG. 4A particularly is a top perspective view of an electrical circuit board 400 that can be implemented in a storage pod having a computer portion stacked with a hard drive. The electrical circuit board 400 is shown in to include an embedded computer 402, which can be considered to correspond to the embedded computer 306 of FIG. 3B, as well as other circuit components 404. Further, FIG. 4B is an image providing a bottom perspective view of a hard drive (e.g., disk drive, HDD, SDD, etc.) 406 with the circuit board 400 of FIG. 4A mounted thereon. In FIG. 4B, the electrical circuit board 400 further is shown to include a backplane connection (or connector, port, or terminal) 408, which can be considered to correspond to the backplane connection 312.

As for FIG. 4C, there is provided an image showing a bottom perspective view of a storage pod 410 that can be implemented to include the hard drive 406 and electrical circuit board 400 of FIGS. 4A and 4B. Also, the storage pod 410 is shown to include an external housing or carrier 411 with a door section 412 that is hinged relative to the remainder of the carrier and that is shown in an open position. The storage pod 410 can be considered to correspond to the storage pod 300, or be considered to constitute a storage pod that is similar in its characteristics to the storage pod 300 in terms of having a computer portion that is stacked with a hard drive. It should be appreciated that assembly of the storage pod 410 can involve attaching the electrical circuit board 400 to the back of the hard drive 406, and setting the hard drive and electrical circuit (compute) board into the carrier (or drive carrier) 412, where all three components become the storage pod.

Turning to FIG. 5, a block diagram 500 illustrates example processing (and related) components that can be employed in storage pods such as those of FIGS. 1-4C for the purpose of providing or implementing object storage processing or software-defined storage. FIG. 5 particularly depicts the processing components (processor, or computer/compute components configured to satisfy the overall processing needs) of a storage pod, such as the storage pods 104, 106, 300, and 410, additionally in relation to several other components of such a storage pod or a storage appliance such as the storage appliance 100 in relation to which the storage pod is implemented (shown in phantom).

More particularly as shown by the block diagram 500, the processing components (processor, or computer/compute components) of a storage pod include one or more central processing unit (CPU) components 502, a non-volatile memory component (or components) 504, and several additional components 506. With respect to the CPU components 502, FIG. 5 includes four CPU components, namely, a CPU Core 1, a CPU Core 2, a CPU Core 3, and a CPU Core 4. In alternate embodiments, a different number (lesser than or greater than four) CPU components can be present. With respect to the non-volatile memory 504, typically this is configured to provide at least a small amount of memory, and in the present embodiment this includes a 6 GB (Gigabyte) SDRAM (Synchronous Dynamic Random Access Memory) chip. In other embodiments, the amount of memory can be greater or lesser than 6 GB or can be of a different form other than SDRAM.

Further, in the present example embodiment, the additional components 506 include a power management component 508, a 16 GB NAND (Not And) component 510, and a NAND controller 512. The 16 GB NAND component 510 can in some embodiments be a flash device and, along with the non-volatile memory 504 can store information that is utilized by the NAND controller 512 and the CPU components 502 for their operation. It should be appreciated that all of the CPU components 502, non-volatile memory 504, and additional components 506 are electrically interconnected and can communicate with one another, for example, by way of a bus (not shown).

In addition to the CPU components 502, non-volatile memory 504, and additional components 506, the block diagram 500 also includes a SATA (Serial ATA) block 514 and an edge connector block 516. The SATA block 514 facilitates communications between the CPU components 502, non-volatile memory 504, and additional components 506 as appropriate relative to a physical storage device 518, which is shown in phantom as an indication that that the physical storage device is distinct from the processing (and related) components represented by the block diagram 500. Although distinct from the processing (and related) components represented by the block diagram 500, the physical storage device 518 nonetheless is part of the storage pod of which the processing (and related) components also form a part. Depending upon the embodiment, the physical storage device 518 can take on or include any of a variety of forms of memory devices or components (or combinations of devices or components) and can, for example, be a hard drive corresponding to any of the hard drives 200, 310, or 406 described in relation to FIGS. 1-4C. Although the present embodiment employs the SATA block 514, in other embodiments other components allowing for communications between the processing (and related) components and one or more memory devices of can be employed including, for example, other computer bus interface communications components or a Serial Attached SCSI (SAS, with SCSI referring to a Small Computer System Interface) block.

As for the edge connector block 516, this can be considered to be an interface component that allows for interaction, via a backplane such as the backplane 110 (not shown in FIG. 5), with other components of the storage appliance and/or that are in communication with the storage appliance. Such components can include, for example, a network interface 520, a display port 522 (which can be linked to a display device such as the status display 120), and a power supply 524, such as the power supply 116. All of the network interface 520, display port 522, and power supply 524 are shown in phantom in FIG. 5 as an indication that these devices are distinct from the processing (and related) components represented by the block diagram 500 and, indeed, distinct from any storage pod of which the processing (and related) components of FIG. 5 form a part.

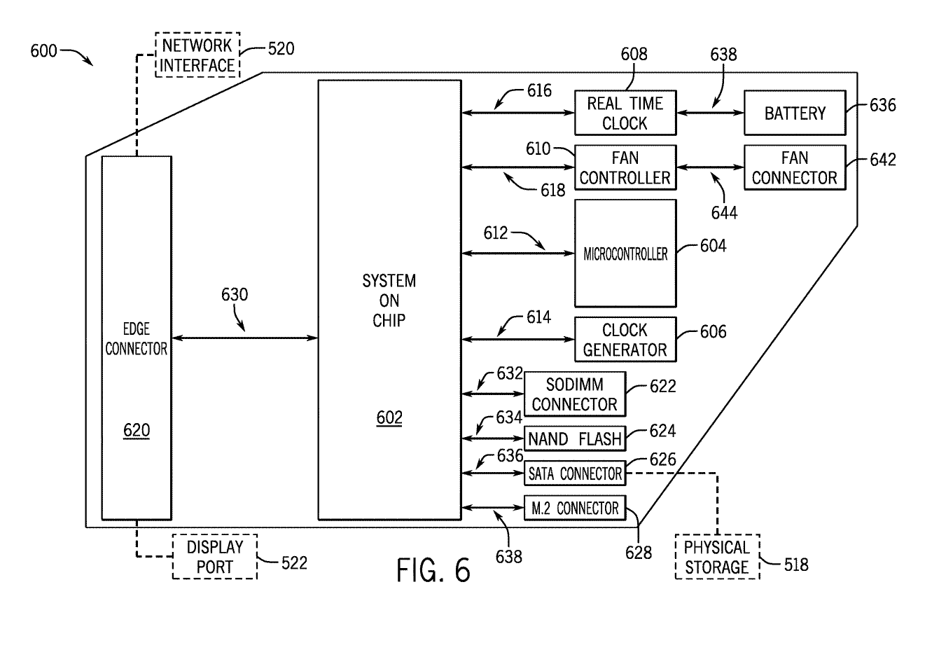

Referring to FIG. 6, a further block diagram 600 illustrates example processing (and related) components that can be employed in storage pods such as those of FIGS. 1-4C for the purpose of providing or implementing object storage processing or software-defined storage, and that differ from the processing components described with respect to FIG. 5. FIG. 6. particularly depicts the processing components (processor, or computer/compute components configured to satisfy the overall processing needs) of a storage pod such as the storage pods 104, 106, 300, and 410, as shown by block diagram 600, additionally in relation to several other components of such a storage pod or a storage appliance such as the storage appliance 100 in relation to which the storage pod is implemented (shown in phantom).

In the embodiment of FIG. 6, as shown by the block diagram 600, the processing components of the storage pod particularly include a system on a chip (SOC) 602, a microcontroller 604, a clock generator 606, a real time clock 608, and a fan controller 610. Additionally as shown, the SOC 602 is (either directly or indirectly) coupled to and configured for communication with each of the microcontroller 604, clock generator 606, real time clock 608, and fan controller 610, respectively, by way of communication links 612, 614, 616, and 618, respectively. Also, although not shown, it should be appreciated that there can be additional communication links that allow for additional direct or indirect communications between the microcontroller 604 and each of the clock generator 606, real time clock 608, and fan controller 610 (e.g., by way of communication pathways other than via the SOC 602).

Further as shown, the processing (and related) components of the block diagram 600 additionally include an edge connector 620, a SODIMM (small outline dual in-line memory module) connector 622, a NAND Flash component 624, a SATA connector 626, and a M.2 (or NGFF or Next Generation Form Factor) connector 628. The SOC 602 is (either directly or indirectly) coupled to and configured for communication with each of the edge connector 620, SODIMM connector 622, NAND Flash component 624, SATA connector 626, and M.2 connector 628, respectively, by way of communication links 630, 632, 634, 636, and 638, respectively. The SODIMM connector 622 can be coupled to, and allow for communication with, a SODIMM by way of a communication link therebetween (not shown), with such a SODIMM not being considered one of the processing components represented by the block diagram 600. Each of such a SODIMM coupled to the SODIMM connector 622, as well as the NAND Flash component 624, can provide persistent memory and can store information that is utilized by the SOC 602 and other processing (and related) components represented by the block diagram 600 for their operation.

Similar to the embodiment described with respect to FIG. 5, the SATA connector 626 of FIG. 6 facilitates communications between the processing components (e.g., the SOC 602) represented by the block diagram 600 and a physical storage device, which is shown again as the physical storage device 518 mentioned above in relation to FIG. 5. As with FIG. 5, the physical storage device 518 is shown in phantom as an indication that that the physical storage device is distinct from the processing (and related) components represented by the block diagram 600. Although the physical storage device 518 is distinct from the processing (and related) components represented by the block diagram 600, the physical storage device 518 nonetheless is part of the storage pod of which the processing (and related) components also form a part. Further as in the case of FIG. 5, it should be appreciated that the physical storage device 518 coupled to the SATA connector 626 can take any of a variety of forms depending upon the embodiment or implementation. For example, in at least some embodiments, the physical storage device 518 is a hard disk drive and, in at least some other embodiments, the physical storage device 518 coupled to the SATA connector 626 can include multiple distinct physical storage devices. Further, although the present embodiment employs the SATA connector 626, in other embodiments other components can be employed including, for example, an SAS block.

Additionally, although the present embodiment includes the SATA connector 626 that allows for communications with the physical storage device (or multiple physical storage devices) 518, in the present embodiment the M.2 connector 628 is also provided that allows for communication with possibly one or more other physical storage devices (not shown). The M.2 connector 628 can be coupled to and allow for communications with any of a variety of different types of physical storage devices depending upon the embodiment or implementation. Nevertheless, it should be appreciated that the M.2 connector 628 is particularly suited for being coupled to and allowing for communications with a flash drive (and thus the M.2 connector can be considered to be a flash drive connector).

As for the edge connector block 616, this can be considered to be an interface component that allows for interaction, via a backplane such as the backplane 110 (not shown), with other components of the storage appliance and/or that are in communication with the storage appliance. Such components can include, for example, the network interface 520 as well as the display port 522 shown in FIG. 6, which were already described in relation to FIG. 5. As with respect to the physical storage device 518 shown in FIG. 6, the network interface 520 and display port 522 are shown in phantom lines as an indication that these are components that are distinct from the processing (and related) components represented by the block diagram 600 and, indeed, distinct from any storage pod of which the processing (and related) components of FIG. 6 form a part.

Additionally as shown in FIG. 6, the processing (and related) components represented by the block diagram 600 also include a battery 636 that is (either directly or indirectly) coupled to and in communication with the real time clock 608 as represented by a communication link 638, and a fan connector 642 that is (either directly or indirectly) coupled to and in communication with the fan controller 610 as represented by a communication link 644. As already mentioned, the real time clock 608 and fan controller 610 respectively are coupled to the SOC 602 by way of the communication links 616 and 618, respectively, and in at least some embodiments, the communication link 618 can be or include one or more thermal diodes. It should be appreciated that the fan connector 642 also can be coupled to a fan by way of an additional communication link (not shown). With such an arrangement, fan control signals provided from the fan controller 610 can be transmitted to the fan, via the communication link 644 and the fan connector 642 (as well as the additional communication link connecting the fan connector with the fan, not shown). Additionally, information regarding the speed of the fan (and/or possibly other fan characteristics, such as fan temperature) can be communicated from the fan to the fan connector 642 (by way of the additional communication link, not shown) and then further from the fan connector 642 to the fan controller 610 via the communication link 644.

It should be understood that, although FIG. 6 shows example components and devices, and communication links coupling those components and devices, these are merely exemplary and these features can vary depending upon the embodiment. Among other things, it should be appreciated that the numbers and types of communication links among the various components can vary depending upon the implementation or embodiment and that, in some embodiments, other circuit components or devices are present, such as level shifters or headers that facilitate desired communications or manners of operation.

In view of each of the embodiments represented by FIGS. 5 and 6, it can be seen that the processing (and related) components perform a variety of roles within the storage pod that include but are not limited to processing and control functionality. In particular, among other things, the processing (and related components) of the storage pod enable the storage pod to achieve connectivity with the backplane 110 via a standardized (e.g., Ethernet) port or terminal. This connectivity includes both network communications connectivity as well as power connectivity, such that the storage pod and the physical storage device thereof can achieve both the communication of information and data and the communication of power relative to (so as to receive both information and data, and power, from) the backplane 110. In at least some embodiments, the storage pods are modular storage devices that are fully capable of acting as API (application program interface or application programming interface) endpoints for application data storage.

Further, in at least some embodiments, the processing (and related) components of the storage pods—and, indeed, the storage pods overall—are configured in a manner such that unnecessary components are not provided on the storage pods. For example, notwithstanding any of the above discussion, in at least some embodiments, the storage pods do not have any one or more of the following features or capabilities: a graphics interface; a universal serial bus (USB) port; an audio port; a PCI express interface; any features that allow the storage pods to be configured to include additional ports or capabilities other than those described above or below.

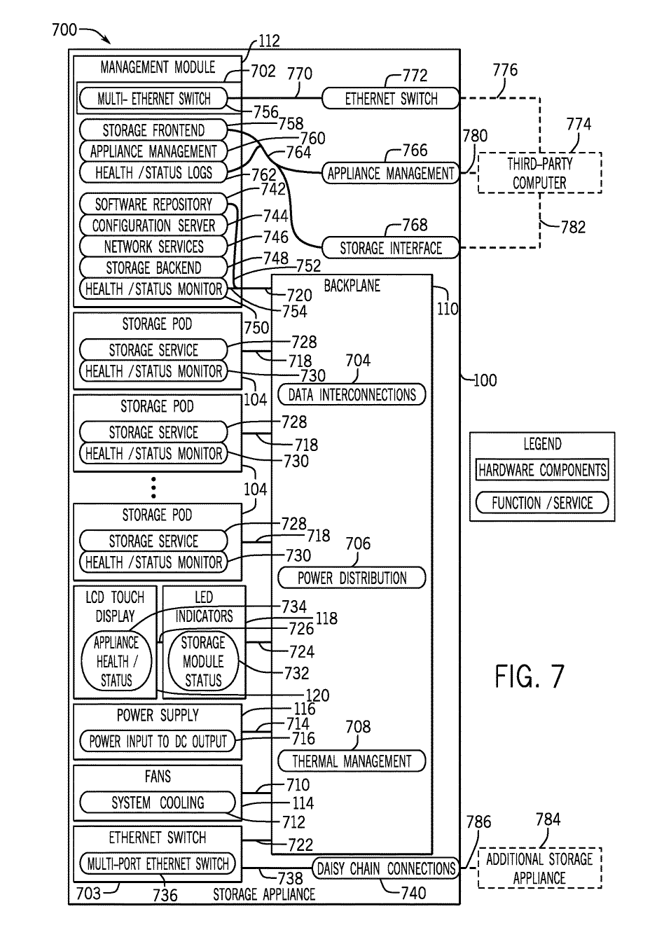

Referring next to FIG. 7, a schematic diagram 700 is provided to illustrate functions/services (e.g., functional blocks, or functional components or modules) of the storage appliance 100 shown in FIG. 1. For purposes of describing an example, the storage appliance 100 (as shown in FIG. 1) includes the backplane 110, the management module 112, the fans 114, and the power supply 116, as well as the storage pods 104, the status indicators 118, and the status display 120. The storage pods 104 of FIG. 7 more particularly can be understood to take any of the forms and include any of the features described in relation to any of FIGS. 1-6. Also, in the embodiment of FIG. 7, the status indicators 118 are LED (light emitting diode) indicators and the status display 120 is a LCD (liquid crystal display) touch display. Additionally, although not shown in FIG. 1, the storage appliance 100 as shown in FIG. 7 further includes a first Ethernet switch 702, which can be a 10G switch and which is part of the management module 112, and also a second Ethernet switch 703, which can be or include a SFP+ (small form-factor pluggable) breakout component. By virtue of the first and second Ethernet switches 702 and 703, the storage appliance and storage pods thereof can be viewed as providing switched Ethernet operation. Although not shown in detail, it should be recognized that the second Ethernet switch 703, when taking the form of the SFP+ breakout component, can be formed by the combination of a XFI SFP+ transceiver coupled between an edge connector and multiple SFP+ connector/cage components, along with an I2C multiplexer coupled between the edge connector and the multiple SFP+ connector/cage components.

As shown in FIG. 7, the backplane 110 provides several functions within the storage appliance 100. These functions include a data interconnections function 704, a power distribution function 706, and a thermal management function 708. With respect to the thermal management function 708, this function particularly involves operations of the backplane 110 to intercommunicate with, monitor, and control operation of the fans 114 by way of a communication link 710 coupling the backplane 110 with the fans 114. The fans 114, in turn, provide a system cooling function 712, and this system cooling function can be understood both to include physical cooling of the storage appliance 100 as well as receiving and executing commands from the backplane 110 and communicating information (e.g., status information such as fan speed or operational temperature) to the backplane 110.

Additionally, with respect to the power distribution function 706 performed by the backplane 110, this function involves intercommunications between the backplane 110 and the power supply 116 by way of a communication link 714. The communications between the backplane 110 and the power supply 116 can involve both the communication of power (e.g., direct current or DC output power) from the power supply 116 to the backplane 110 and also the communication of information between the backplane and power supply, including control signals directed from the backplane to the power supply 116 and informational signals directed from the power supply to the backplane that allow for monitoring of the power supply. As shown, the power supply 116 particularly provides a power input to DC output function 716. In accordance with this function 716, DC output power is supplied by the power supply as a result of power conversion performed by the power supply, more particularly, power conversion in which input power (e.g., alternating current or AC power) received by the power supply from another source is converted into the DC output power that is then provided to backplane 110.

Further, with respect to the data interconnections function 704 performed by the backplane 110, this function involves operation of the backplane to allow for the intercommunication of signals and information among each of the storage pods 104, the management module 112, the second Ethernet switch 703, and the status indicators 118 and the status display 120. As illustrated, such intercommunication of signals and information occurs by way of respective communication links between the backplane 110 and each of the respective storage pods 104, the management module 112, the Ethernet switch 703, and the status indicators 118, namely, respective storage pod communication links 718 coupling the backplane 110 with the respective storage pods 104, a management module communication link 720 linking the backplane 110 with the management module 112, an Ethernet switch communication link 722 linking the backplane 110 with the second Ethernet switch 703, and an indicator communication link 724 linking the backplane 110 with the status indicators 118. As further illustrated, the status display 120 is indirectly coupled to the backplane 110 by way of the status indicators 118 and the indicator communication 724 and also by way of a further communication link 726 connecting the status indicators 118 with the status display 120. It should be appreciated that each of the respective storage pod communication links 718 at least in part can correspond to the backplane connection 208 shown in FIG. 2.

Additionally as shown in FIG. 7, the storage pods 104, management module 112, status indicators 118, status display 120 and Ethernet switch 703 perform several different functions. With respect to the storage pods 104 in particular, each of the storage pods as shown can perform a respective storage service function 728 as well as a respective health/status monitor function 730. The respective storage service function 728 of each respective one of the storage pods 104 is a function according to which information or data is received by the storage pod 104 and stored in memory (e.g., at the physical storage device 518) available at the storage pod, e.g., “write functionality,” and also according to which information or data stored at the storage pod is output by the storage pod for receipt by the backplane 110, e.g., “read functionality.” The respective health/status monitor function 730 of each of the storage pods 104 is a function according to which the storage pod monitors its operational status and health characteristics and can provide information regarding those characteristics to another device such as the management module 112 by way of the backplane 110. Such operational status and health characteristics can include, for example, the amount of total memory capacity of the storage pod that remains available and unused and can be used for storing further information, or information regarding the temperature of the storage pod.

With respect to the status indicators 118, as shown in FIG. 7 the status indicators perform a function of providing indications of storage pod status 732, where the indications can be determined based upon the health/status information provided from the respective storage pods 104 as a result of the performing of the health/status monitoring function 730 at the respective storage pods. In at least some embodiments, for example as illustrated in FIG. 1, there can be respective individualized status indications provided concerning each respective one of the storage pods 104. For example, when the status indicators 118 are LED indicators, each respective LED indicator corresponding to a respective one of the storage pods 104 can be lit when the respective storage pod is respectively plugged into the backplane 110 and/or is active and ready to store information, and also can be blinking if the storage capacity of the respective storage pod has been exhausted. As for the status display 120, the status display performs an appliance health/status function 734, that is, a function of indicating operational status or health information pertaining to the overall storage appliance 100 rather than merely to one of the storage pods 104.

Further, with respect to the management module, 112, that module performs numerous functions/services as illustrated in FIG. 7. These functions include a software repository function 742, a configuration server function 744, a network services function 746, a storage backend function 748, and a health/status monitor function 750. As represented by links 752 and 754 that connect the communication link 720 with the software repository function 742 and the health/status monitor function 750, respectively, the management module 112 particularly engages in communications with the backplane 110 in relation to performing to each of the software repository function 742, configuration server function 744, network services function 746, storage backend function 748, and health/status monitor function 750. That is, all of the functions 742, 744, 746, 748, and 750 are directed toward the backplane 110.

More particularly with respect to the software repository function 742, the management module 112 serves to communicate software instructions or programming, which can (among other things) entail the communicating of software to one or more of the storage pods 104 that allow those storage pods to operate in desired manners, e.g., in terms of storing received information or data and providing or outputting stored information or data upon request. As will be described further below, in at least some embodiments the communicating of software can include the communicating of Ceph software in accordance with the Ceph software storage platform available from/developed by Red Hat, Inc. of Raleigh, N.C. Also, with respect to the health/status monitor function 750, this function can involve receiving and collecting operational status and/or health information regarding the storage appliance 100, including for example information provided from the storage pods 104 in accordance with the health/status monitor function 730 performed by each of those storage pods. Additionally, the health/status monitoring function 750 can entail providing instructions or commands via the backplane 110 to the status indicators 118 and status display 120 so that the status indicators and/or status display can output indications of the operational health and status of the storage appliance 100 or one or more of the storage pods 104 or other components thereof (e.g., for viewing by a user of the storage appliance).

In addition to the functions/services of the management module 112 already described, the management module additionally performs several other functions/services as well. In particular, the first Ethernet switch 702 of the management module 112 performs a multi-port Ethernet switch (or switching) function 756. Additionally, the management module 112 also provides a storage front end function 758, an appliance management function 760, and a health/status logs function 762. As is represented by a link 764, the storage front end function 758, appliance management function 760, and health/status logs function 762 are in communication with, and can be understood as providing or creating, each of an appliance management service 766 and a storage interface service 768 of the storage appliance 100. Further, as is represented by a link 770, the multi-port Ethernet switch function 756 is in communication with, and can be understood as providing or creating, an Ethernet switch service 772 of the storage appliance 100.

Further as illustrated, the Ethernet switch service 772, appliance management service 766, and storage interface service 768 particularly are services that are configured to be accessed by, and to facilitate intercommunications of the storage appliance 100 with, one or more other computers or systems such as a third-party computer 774. Such one or more other computers or systems, such as the third-party computer 774, are distinct from and not part of the storage appliance 100, but nevertheless can engage in communications with and access the storage appliance 100 by way of one or more communication links. By way of example, the third-party computer 774 is shown to be in communications with each of the Ethernet switch service 772, the appliance management service 766, and storage interface service 768, respectively, by way of communication links 776, 780, and 782, respectively. Each of the third-party computer 774 and the communication links 776, 780, and 782 are shown in phantom to highlight that these items are all distinct from, and not part of, the storage appliance 100

It should be appreciated that the communication links 776, 780, and 782 are shown for illustration purposes, and are intended to be representative of any of a variety communication links between any one or more other devices or systems such as the third-party computer 774 and the storage appliance 100. Indeed, in some embodiments, communications between the third-party computer 774 (or other devices or systems) with the storage appliance 100 can be achieved with only a single communication link. Also, it should be understood that the communication links 776, 780, and 782 linking the third-party computer 774 (or other devices or systems) with the storage appliance 100 can take any of a variety of forms including, for example (but not limited to), dedicated, wired, or wireless communication links, as well as communication links that involve Internet-based communications or communications via the World Wide Web. Further, the third-party computer 774 (or other devices or systems) that are in communication with or accessing the storage appliance 100 can be located physically proximate to, or remotely from, the storage appliance.

It should also be appreciated that, depending upon the embodiment, the storage appliance 100 can be in communication with any of a variety of different types of computers or systems including server computer systems or client computer systems, all of which are generally intended to be represented by the third-party computer 774 shown in FIG. 7. In some embodiments, such computer systems (again represented by the third-party computer 774) can be home personal computers that are linked up to the storage appliance 100 by way of Ethernet or other communication links. Additionally, in some embodiments in which the storage appliance 100 is in communication with a client computer system, the storage appliance (and the management module 112 thereof) can be configured to allow for the sending of web screen information based upon which the client computer system can display one or more web pages that serve as a web-based management interface.

By providing a web-based management interface at the client computer system, a client or user utilizing the client computer system can monitor information or data regarding the status or operation of the storage appliance 100 (e.g., allowing for “smart status” operation). Additionally by providing such an interface at the client computer system, a client or user can also provide input signals that cause the client computer system to generate command or control signals that are sent to the storage appliance 100 so as to govern or influence operation of the storage appliance or portions thereof, such as the management module 112 or one or more of the storage pods 104. In some such embodiments, a client or user utilizing a client computer system can log in remotely to the management module 112 of the storage appliance 100 for interactions therewith by way of a SSH (Secure Shell) connection.

More particularly with respect to monitoring functionality, the information or data that can be provided from the storage appliance 100 to the client computer system for display via the web-based management interface can include, for example, information regarding the overall health of the storage appliance as well specific operational or status details of the storage appliance. Further for example, such details can include times at which the storage pods 104 are installed as part of the storage appliance (or notifications of installation), operational or status characteristics or features of the storage pods 104 that have been installed, the proportion of overall memory afforded by the storage appliance that is currently being used, and the temperature of a given hard disk drive associated with one of the storage pods 104.

Additionally, more particularly with respect to control functionality, a client or user can provide inputs to the client computer system via the web-based management interface that cause the client computer system to generate and send command signals to the storage appliance 100 that in turn cause any of a number of actions to take place at the storage appliance, one or more of the storage pods 104, the management module 112, or other portions of the storage appliance. Further for example, the command signals generated or sent by the client computer system can influence or govern the configuration of one or more features of the storage appliance or one or more portions thereof (including any of the storage pods 104 thereof), the storage of information or data onto the storage pods 104, or the retrieval of information or data from the storage pods 104.

As already mentioned, in addition to the first Ethernet switch 702, the storage appliance 100 also includes a second Ethernet switch 703, and the second Ethernet switch as shown also provides a multi-port Ethernet switch function 736. Further, as represented by a link 738, the multi-port Ethernet switch function 736 is in communication with, and can be understood as providing or creating, a daisy chain connections service 740. The daisy chain connections service 740 particularly allows for one or more additional storage appliances such as an additional storage appliance 784 to be coupled to, and in communication with, the storage appliance 110, as represented by a communication link 786 (e.g., multiple storage appliances/hardware enclosures each potentially with multiple storage pods can be linked together by Ethernet connectivity linking the backplanes of the different enclosures). The additional storage appliance 784 and communication link 786 are shown in phantom to highlight that these items are distinct from, and not part of, the storage appliance 100. As with the communication links 776, 780, and 782, the communication link 786 is intended to represent communication links that can take any of a variety of forms depending upon the embodiment or implementation.

During operation of an overall system in which multiple storage appliances such as the storage appliance 100 are daisy chain linked together in this manner, typically the management module 112 at one of the storage appliances 100 will be active and be in control of, and operate to recognize and govern the operation of, all of the storage pods that are present at all of the storage appliances. Correspondingly, the management modules at the others of the storage appliances will be dormant. Although in the present embodiment the multiple storage appliances are described as being daisy chain linked together, in other embodiments the manner or connecting or linking the multiple storage appliances of the overall system can take other forms.

Although FIG. 7 shows the presence of the additional storage appliance 784, no additional storage appliance(s) need be present or connected to the storage appliance 100 in any given implementation or embodiment. Indeed, whether any additional storage appliance(s) are present, as well as the number (and features) of any such additional storage appliance(s), can vary depending upon the embodiment or implementation. Nevertheless, the presence of the second Ethernet switch 703 and multi-port Ethernet switch function 736 and daisy chain connections service 740 allows for the storage appliance 100 to be readily expanded to encompass effectively any arbitrary number of the storage pods 104 installed in relation to any arbitrary number of storage appliances (e.g., more storage pods than can be housed in the storage appliance 100) and provide any arbitrary amount of memory. Thus, the storage capacity of the storage appliance 100 is not strictly limited to the amounts of storage capacity that can be provided by the finite number of storage pods 104 can be inserted into the main section 102 at the slots 121, but rather can be increased to encompass additional storage capacity afforded by additional storage pods that are positioned elsewhere.

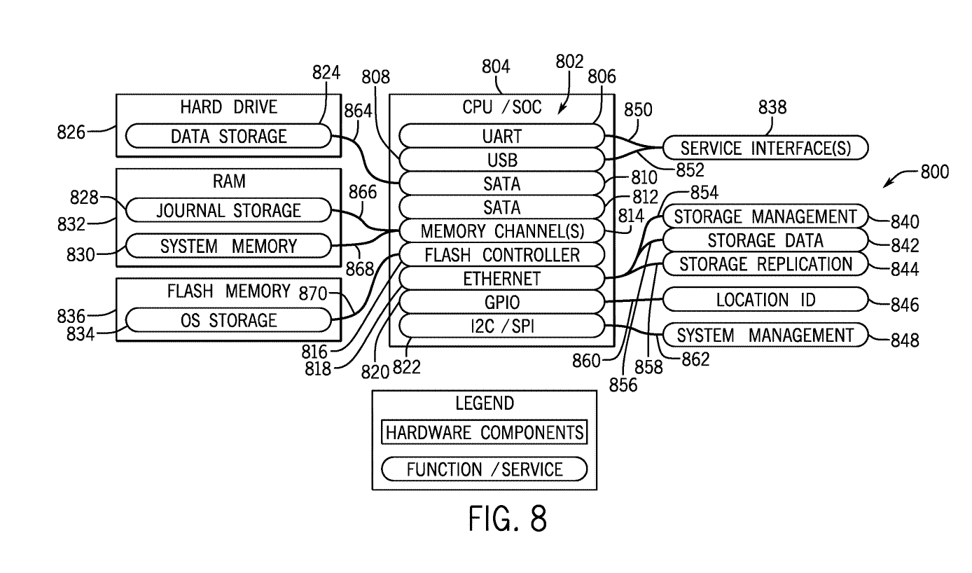

Turning to FIG. 8, an additional schematic diagram 800 is provided to illustrate in more detail the functions/services (e.g., functional blocks, or functional components or modules) associated with storage pods such as the storage pods 104, 106, 300, and 410 of FIGS. 1-4C, some of which correspond to the operation of the processing (and related) hardware components shown in FIGS. 5 and 6. The functions/services shown in FIG. 8 can be understood as particularly corresponding to, and showing in more detail, aspects of the storage service and health/status monitor functions 728 and 730 of the storage pods 104 shown in FIG. 7. The schematic diagram 800 also shows how functions/services associated with particular hardware components of the storage pods 104, 106, 300, and 410 interact with one another.

In the embodiment of FIG. 8, multiple functions/services 802 are performed by a CPU or SOC 804. The CPU or SOC 804 can be for example any of the embedded computers 202, 306, 402 described above. Also, the CPU or SOC 804 can correspond to any one or more of the CPU components 502 of FIG. 5 when in the form of a CPU, and can correspond to the SOC 602 of FIG. 6 when in the form of a SOC. More particularly as shown, the multiple functions/services 802 include a universal asynchronous receiver/transmitter (UART) function 806, a Universal Serial Bus (USB) function 808, first and second SATA functions 810 and 812, respectively, one or more memory channels 814, a Flash Controller function 816, an Ethernet function 818, a General Purpose Input/Output (GPIO) function 820, and an I2C/SPI (inter-integrated circuit/SCSI parallel interface) function 822. These functions/services are merely exemplary and, in other embodiments, one or more other functions/services can be provided in addition to or instead of these services. For example, in other embodiments, any one or more of a Device Driver Interface (DDI) function, a MultiMediaCard (MMC) function, and one or more (e.g., three or four) Peripheral Component Interconnect Express (PCIe) functions can also or instead be provided.

In addition to the functions/services 802 associated with the CPU or SOC 804, as shown in FIG. 8 there are also additional functions/services that are performed that are associated with other hardware components of the storage pod. These include a data storage function 824 performed by a hard drive component 826, a journal storage function 828 and a system memory function 830 performed by a random access memory (RAM) component 832, and an operating system (OS) storage function 834 performed by a Flash Memory component 836 (which in alternate embodiments can be an embedded MultiMediaCard (eMMC) component). It should be appreciated that the hard drive component 826 can be the physical storage device 518 of FIGS. 5 and 6, the Flash Memory component 836 can be the NAND Flash component 624 of FIG. 6, and the RAM component 832 can be the non-volatile memory 504 of FIG. 5, for example. Further, there are provided one or more service interface(s) 838, a storage management interface 840, a storage data interface 842, a storage replication interface 844, a location identification (ID) interface 846, and a system management interface 848, each of which also is a function/service.

The various function/services shown in FIG. 8 communicate or interact with one another in particular manners as illustrated by several connecting links. In particular, it should be appreciated that the service interface(s) 838 are in communication with or interact with the UART function 806 and the USB function 808, respectively, as represented by connecting links 850 and 852, respectively. Additionally, the Ethernet function 818 is in communication with (or interacts with) each of the storage management interface 840, the storage data interface 842, and the storage replication interface 844, as indicated by connecting links 854, 856, and 858, respectively. Further, the GPIO function 820 is in communication with (or interacts with) the location ID interface 846 as indicated by a connecting link 860, and the I2C/SPI function 822 is in communication with (or interacts with) the system management interface 848 as indicated by a connecting link 862. Further, the SATA function 810 is in communication with (or interacts with) the data storage function 824 as indicated by a connecting link 864, the memory channel(s) 814 are in communication with (or interact with) each of the journal storage function 828 and system memory function 830 as indicated by connecting links 866 and 868, respectively, and the Flash Controller function 816 is in communication with the OS storage function 834 as indicated by a connecting link 870.

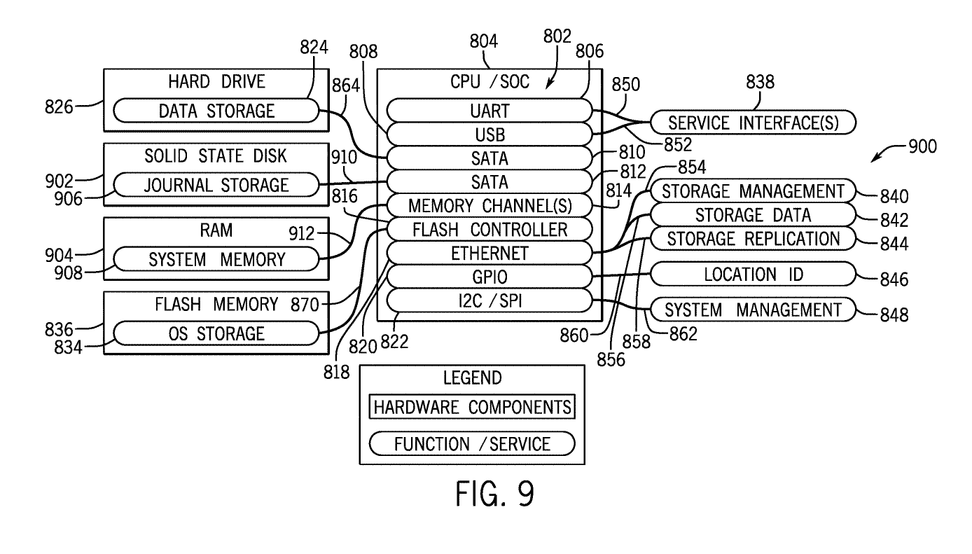

Turning to FIG. 9, an additional schematic diagram 900 is provided to illustrate in more detail, in accordance with an alternate embodiment differing somewhat from that of FIG. 8, the functions/services (e.g., functional blocks, or functional components or modules) associated with storage pods such as the storage pods 104, 106, 300, and 410 of FIGS. 1-4C. As with the functions/services described in relation to FIG. 8, the functions/services shown in FIG. 9 in at least some embodiments correspond to (e.g., can be performed by) the processing (and related) hardware components shown in FIGS. 5 and 6, and the functions/services shown in FIG. 9 can be understood as particularly corresponding to, and showing in more detail, aspects of the Storage Service and Health/Status Monitor functions/services 728 and 730 of the storage pods 104 shown in FIG. 7. The schematic diagram 900 particularly shows how functions/services associated with particular hardware components of the storage pods 104, 106, 300, and 410 interact with one another.

As shown, the functions/services of FIG. 9 are in large part the same as those of FIG. 8. In particular, the functions/services of FIG. 9 includes the multiple functions/services 802 that are performed by the CPU or SOC 804. Also, the functions/services of FIG. 9 include the data storage function 824 performed by the hard drive component 826 that is in communication with the first SATA function 810 as represented by the connecting link 864, and the OS storage function 834 performed by the Flash Memory component 836 and is in communication with the Flash Controller function 816 as represented by the connecting link 870. Further as in the embodiment of FIG. 8, there are provided the one or more service interface(s) 838, the storage management interface 840, the storage data interface 842, the storage replication interface 844, the location identification (ID) interface 846, and the system management interface 848, each of which also is a function/service, and which respectively are coupled to ones of the functions of the CPU or SOC 804 by way of the connecting links 850, 852, 854, 856, 858, 860, and 862 in the same manner as described in relation to FIG. 8.

Although the functions/services of FIG. 9 are in large part the same as for FIG. 8, there are several differences. In particular, the embodiment of FIG. 9, instead of employing the RAM component 832 that provides both the journal storage function 828 and the system memory function 830, rather employs both a solid state disk component 902 that provides a journal storage function 906 and a RAM component 904 that provides a system memory function 908. As illustrated, the journal storage function 906 is in communication with the second SATA function 812 as represented by a connecting link 910 and the system memory function 908 is in communication with the memory channel(s) 814 as represented by a connecting link 912.

The present disclosure is intended to encompass numerous different manners of operation of the storage appliances and storage pods encompassed herein such as the storage appliance 100 and storage pods 104. These processes of operation include one or more processes of installation (or implementation), as well as one or more processes of operation that occur after the processes of installation (or implementation) have occurred and information is stored on or retrieved from the storage pods 104. It should be appreciated that, as already discussed above, any of a variety of different types of storage pods can be implemented and installed in relation to a storage appliance such as the storage appliance 100, including storage pods having any of a variety of different types of storage media implemented thereon such as, further for example, rotating media or flash-based storage media.

Given this to be the case, when a storage pod such as (but not limited to) one of the storage pods 104 is inserted and installed in relation to the storage appliance 100, part of the process of installation involves taking actions to assure that the overall storage appliance 100 (in particular the management module 112 thereof) recognizes the presence and features of the storage pod that has been installed. Upon recognition of the presence and features of the storage pod, the storage appliance 100 (and particularly the management module 112 thereof) can take actions to adapt to the features of the storage pod, to facilitate engagement or interactions between the storage pod and the remainder of the storage appliance (and particularly the management module 112), and to cause corresponding adjustments to be implemented at the storage pod that also facilitate such engagement or interactions.

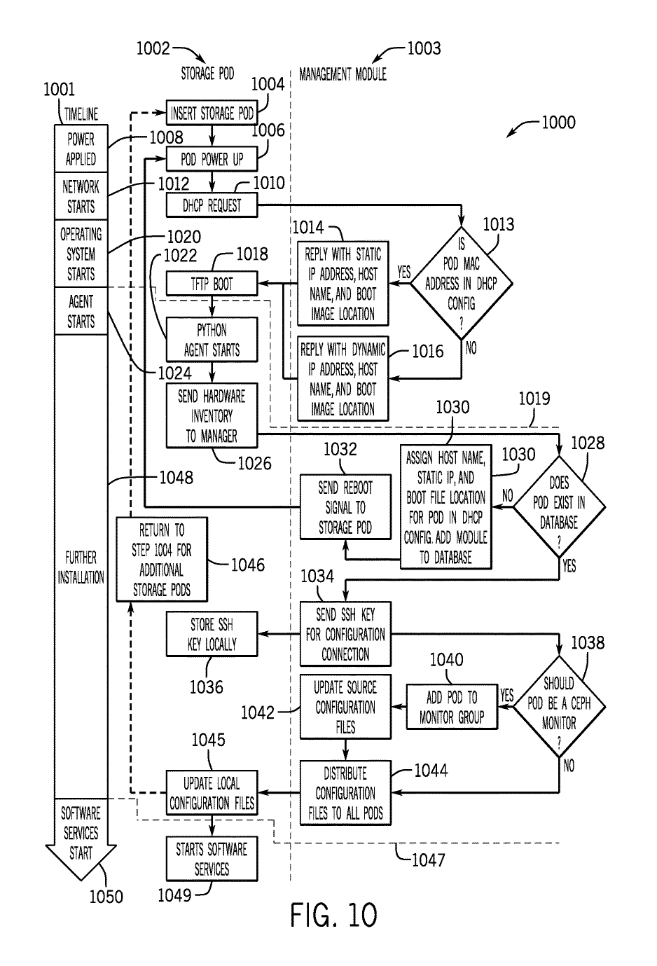

Further in this respect, FIG. 10 provides a flow chart 1000 that shows example steps of an example process of installation (or implementation) of a storage pod such as one of the storage pods 104 in relation to a storage appliance such as the storage appliance 100. The flow chart 1000 is illustrated as proceeding in time along a direction illustrated by a timeline 1001, so as to show how the performing of the various steps of the process represented the flow chart 1000 are temporally-ordered. Also, it should be recognized that the flow chart 1000 includes both a first series of steps 1002 that are typically performed by or at the storage pod 104, and a second series of steps 1003 that are performed by the management module 112.

More particularly as shown, the process of the flow chart 1000 begins when one of the storage pods 104 is inserted into the backplane 100 of the storage appliance 100, as represented by a step 1004. After the storage pod 104 is inserted, then at a later time as represented by a step 1006, the storage pod is powered up, and this corresponds to a power applied segment 1008 of the timeline 1002. It should be appreciated that, typically, the storage pod is powered up immediately upon being inserted into the backplane 110 so as to be electrically coupled thereto. Nevertheless, in other embodiments, or circumstances, there is a time delay between the time at which the storage pod is first inserted into the backplane 110 and the time at which power is applied to the storage pod.

Next, at a step 1010, the storage pod 104 generates and sends a DHCP (Dynamic Host Configuration Protocol) request and sends that request onto the backplane 110 for receipt by the management module 112. The generating and sending of this request at the step 1010 can be considered to be a time at which operation of a network including the storage pod 104 begins, as represented by a segment 1012 of the timeline 1002. Subsequently, upon the DHCP request being sent at the step 1010, that request is then received by the management module 112 at a step 1013, and the management module 112 the determines whether the storage pod's MAC (Media Access Control) address is present in the DHCP configuration that currently exists. If the storage pod's MAC address is present, then the management module 112 proceeds from the step 1013 to a step 1014, at which the management module sends a reply for receipt by the storage pod 104. Typically, the reply sent at the step 1014 is a reply having a static IP (Internet Protocol) address, host name, and boot image location. Alternatively, if the storage pod's MAC address is not present in the DHCP configuration as determined at the step 1013, then the process instead advances to a step 1016 at which the management module 112 generates and sends a different reply than that sent at the step 1014. More particularly, at the step 1016, the management module 112 sends a reply that includes a dynamic IP address, host name, and book image location.

Regardless of which reply is sent, either the reply at the step 1014 or the reply generated at the step 1016, in either case the process then advances to a step 1018, at which the storage pod 104 experiences a TFTP (Trivial File Transfer Protocol) boot. As represented by a dashed line 1019, the steps 1113, 1114, 1116, and 1118 of the process represented by the flow chart 1000 are steps associated with the starting of the operating system on the storage pod 104, as represented by a segment 1020 of the timeline 1001. Following the completion of the TFTP boot step 1018, at a next step 1022, a Python agent begins operation at a step 1022. This corresponds to an agent starts segment 1024 along the timeline 1001. It should be appreciated that, in at least some embodiments, the booting of the image that occurs at the step 1018 can occur via IPXE (e.g., booting can occur via the Ethernet).

Following the commencement of the operation of the Python agent at the step 1022, then the process advances further to a step 1026, at which the storage pod 104 assembles and sends a signal with information indicative of the one or more characteristics or features of the storage pod for receipt by the management module 112. As shown in FIG. 10, the information concerning the one or more characteristics or features can be, for example, information concerning hardware inventory of the storage pod 104. Next, at a step 1028 performed by the management module 112, upon the management module receiving the signal sent by the storage pod 104 at the step 1026, the management module then determines whether the storage pod (that is, the storage pod with the hardware inventory identified in the signal received by the management module) exists in a database of the management module (or a database that is accessible by the management module), at a step 1028. If the management module 112 at the step 1028 determines that the database of (or accessed by) the management module does not have any record corresponding to the storage pod 104 with the hardware inventory sent at the step 1026, then the process advances from the step 1028 to a step 1030. Alternatively, if the database of (or accessed by) the management module 112 at the step 1028 does have a record corresponding to the storage pod 104 with the hardware inventory sent at the step 1026, then the process instead advances from the step 1028 to a step 1034.

If the process advances from the step 1028 to the step 1030 as described above, then at the step 1030 the management module 112 particularly assigns a host name, static IP and boot file location for the storage pod in the DHCP configuration, and also adds that storage pod (or record corresponding thereto) to its database. Further, then at a step 1032, the management module 112 generates and sends for receipt by the storage pod 104 a reboot signal, and the process then returns to the step 1006 of the flow chart 1000. Alternatively, if the process advances from the step 1028 to the step 1034, the management module 112 generates and sends a SSH key for configuration connection at the step 1034. As illustrated, the SSH key that is sent is particularly sent for receipt by the storage pod 104, which then at a step 1036 stores the SSH key locally (e.g., on a memory devise associated with that storage device).

In addition, upon the execution of the step 1034, the process further advances to a step 1038, at which the management module 112 additionally determines whether the storage pod 104 should be a Ceph monitor. If the management module 112 determines that the storage pod 104 should be a Ceph monitor, then the process next proceeds to a step 1040, at which the storage pod 104 is added to the monitor group, that is, added to a group of storage pods or other components or devices that perform a monitoring function and are recognized by the management module 112 as serving this role. Next, at a step 1042, the management module 112 further performs a operation of updating storage configuration files. Upon completion of the step 1042, and also if at the step 1038 the management module 112 determines that the storage pod 104 should not be a Ceph monitor, then the process in each case advances to a step 1044.

At the step 1044, the management module 112 distributes the configuration files to all of the storage pods 104 that may be associated with and implemented in relation to the storage appliance 100 (as opposed to merely the storage pod that was inserted at the performing of the step 1004 during this performance of the process). The distribution of the configuration files in turn causes all of the storage pods 104 installed in relation to the storage appliance 100 to update the local configuration files stored at those storage pods, as represented by a step 1045. Upon the performance of the step 1045, the installation/implementation process of the storage pod is complete and, as represented by a further step 1046, this installation/implementation process can be repeated on multiple occasions for multiple storage pods whenever those storage pods happen to be inserted into the backplane 110 of the main section 102 of the storage appliance 100.

Further, upon performing of the step 1045, the storage pod starts software services as represented by a step 1049. Thus, the storage pod 104 begins operation as part of the storage appliance 100 and, among other things, particularly from this point onward is capable of receiving and storing information or data provided from via the backplane 110, as well as capable of retrieving the stored information or data and providing that information to the backplane 110, as governed by the portions of the Ceph application running at the management module 112 and at the storage pod itself. Further as highlighted by a dashed line 1047, the various steps of the process of the flow chart 1000 from the step 1026 through the step 1046 can be regarded as corresponding to a further installation segment 1048 of the timeline 1002, and the step 1049 can be regarded as corresponding to a segment 1050 of the timeline 1002 in which software services commence and thus operation of the storage pods (and particularly the storage pod inserted at the step 1004) begins in earnest, effectively with the file system being present at the storage pod/physical storage device.

From the flow chart 1000 of FIG. 10, it therefore should be appreciated that, in at least some embodiments, when a given one of the storage pods 104 is inserted into the backplane 110 so as to become part of the storage appliance 100, the storage pod particularly detects its own characteristics and sends information regarding its own characteristics to the management module 112. The management module then either has available to itself, or determines, configuration information and sends that configuration information back to the storage pod 104 so as to allow the storage pod to operate in connection with the overall storage assembly. Although it is not the case that all of the steps of this process involve the use of Ceph, in the embodiment of FIG. 10 the process of installation (or implementation) does involve installing a portion of Ceph (Ceph software code) on the storage pod 104 that is appropriate for the storage pod and consistent with its configuration. The installation of the portion of Ceph onto the storage pod 104 can be considered to occur as part of the step 1046, as part of the configuring of the storage pod for operation as part of the storage appliance that also includes the updating of local configuration files. By virtue of this installation/implementation process, the storage pod 104 subsequently is configured to operate to allow for the storing and retrieving of information or data in accordance with the software-defined storage framework governed by the Ceph application.

In view of the above discussion, it should be appreciated that numerous different embodiments of systems and methods for modular software-defined storage are encompassed herein. At least some of the embodiments encompassed herein are systems that employ one or more information storage pods (or modules, cartridges, elements, or blades) that fit into an overall appliance. Additionally, at least some such embodiments employ mobile-class processors that are capable of providing the computational resources that are appropriate or desirable for implementing such storage pods (or modules, cartridges, elements, or blades). After the installation or implementation of one or more of the storage pods in accordance with a process such as that of the flow chart 100 of FIG. 10, the storage appliance then operates to store information or data at the one or more storage pods (“write operation”) and also to retrieve information or data from the one or more storage pods (“read operation”). The storage appliance among other things can facilitate the storing of information or data upon the one or more storage pods that is provided from one or more sources other than the storage appliance itself, such as the third-party computer 774 shown in FIG. 7, and also can facilitate the retrieval of information or data from the one or more storage pods, and the providing of that information or data to one or more other destinations such as the third-party computer 774. Such storage and retrieval operation can be considered to be included among the software services that are shown as commencing at the step 1049 of FIG. 10.

As already mentioned, to achieve such storing and retrieval of information or data in relation to the storage pods, at least some embodiments of the storage appliances encompassed herein employ Ceph, which is an open source application (or open source database program or software platform) that implements software-defined storage through object storage technology. In accordance with the Ceph application, a storage system manages data as objects as opposed to architectures such as file systems, which manage data as a file hierarchy. Each object typically includes the data itself, some metadata, and a unique identifier. Overall, the topology of a Ceph cluster is designed around replication and information distribution, and is configured to provide low-cost data integrity. With the lack of central metadata files and data striped across large node-sets there is no bottleneck in storage access. Compared to traditional storage, Ceph provides capability with good value, particularly because Ceph can be implemented upon commercial off-the-shelf (COTS) hardware (which in some cases can be inexpensive or commodity-priced hardware). Ceph can be classified as “software defined storage (SDS)” where the storage logic is abstracted into a software layer running on hardware. In a storage appliance such as the storage appliance 100, the Ceph software code can be stored both at the management module 112 as well as (to some extent) on the storage pods 104.

Through the use of Ceph, the storage appliance 100 described above particularly can operate to accommodate, in terms of allowing for the storing and retrieval of information or data, a multiplicity of storage pods having different characteristics. For example, the storage appliance 100 in one implementation can have, inserted therein, twelve storage pods, of which eight employ spinning hard disk drives and of which the remaining four employ lower capacity storage devices. In such an implementation, operation by way of Ceph determines how information or data is stored and retrieved from the various storage pods, determines which of the storage devices of the various storage pods are the recipients of information or data being stored, and determines the storage devices of the storage pods from which information or data is retrieved. Ceph can operate advantageously to enhance the efficiency of usage of the various storage devices at the various storage pods, taking into account the particular characteristics of those storage devices (and the storage pod configuration information). For example, information or data that is used or requested (or updated) less frequently can be stored at storage devices that are slower in terms of the time required to access those storage devices, and information or data that is used or requested (or updated) more frequently can be stored at storage devices that are faster in terms of the time required to access those storage devices.

It should be appreciated that at least some of the systems and methods for modular software-defined storage encompassed herein are advantageous in one more respects. For example, in at least some embodiments, the employing of storage pods (or modules, cartridges, elements, or blades) is intended or configured in a manner directed toward minimizing the number or extent of involvement of ancillary components used for object storage processing. Indeed, in at least some such embodiments, the storage pod is configured to have only the required components needed to serve as a storage device in the software-defined storage appliance, and/or is configured to reduce the hardware costs of implementing software-defined storage through the combination of standard, off-the-shelf, commercially-available hard drives that use existing industry standard interfaces and also operate in conjunction with purpose-specific computer hardware. Thus, in at least some embodiments encompassed herein, the storage pod concept can serve as a high performance, cost-optimized or reduced-cost design serving software-defined storage facilities.

Also, because the storage pod concept as described above involves encapsulating a hard drive and processing (and related) components (e.g., compute components) in a single, integrated storage pod (or module, element, or blade), the storage pod concept is purposefully designed to act as a storage building block for a software-defined storage implementation and to facilitate simplified storage expansion. The use of storage pods, in combination with a backplane, creates efficiencies in terms of shared infrastructure allowing for simplified management as well as the ability for each storage cartridge to share power, cooling, and network components and functionality. Thus, in contrast to some conventional software-defined storage implementations that are focused on large-scale deployments (such as those needed for large data centers) and that have been implemented using racks of computers based on workstation or server-class hardware, in the above-described embodiments software-defined storage is implemented on a smaller scale that is particularly suited for providing a cost competitive storage appliance. It is envisioned that such a storage appliance with one or more storage pods will be particularly desirable for small-to-medium-sized business and/or the consumer markets.

Therefore, it should be appreciated that at least some embodiments of storage appliances utilizing one or more storage pods encompassed herein are cartridge are configured so as to allow for maximizing (or at least enhancing) the performance of the software-defined storage architecture, maintaining a relatively small initial investment in hardware, and incrementally increasing the amount of total storage available to a user (or users) in an easy and inexpensive manner. Indeed, the modular nature of the storage pods makes increasing storage easy for the user while the small size of the storage pods makes it financially less expensive to add incremental amounts of storage when needed or desired. More particularly, the storage pod architecture allows for relatively low up-front cost since the processing (and related) components (e.g., compute components) used to support each hard disk (or other storage component) is purchased with the hard disk/hard disk drive (or other storage component). In addition, the communications interconnection between drives is based on lower price commodity components (such as Gigabit Ethernet) reducing the infrastructure cost required.

It should further be appreciated that at least some embodiments of storage appliances utilizing one or more storage pods encompassed herein are configured in a manner such that each storage pod acts as the hardware manifestation of the abstract concept of a storage location in the software-defined storage architecture. Each of the storage pods is a piece of hardware on which the files, objects, or blocks of data in the software-defined storage implementation are physically-stored. Further, each of the storage pods can be employed to allow for the storing and retrieving of data in any of a range of commercial/industrial storage applications. These can include (without being limited to), for example, information technology infrastructure such as in a storage appliance to provide storage for computer networks, embedded applications where the storage infrastructure is built into other OEM (original equipment manufacturer) systems, and consumer-level applications in which a relatively small amount of network based storage is required.

In addition to advantages and uses arising from using the storage pods in a chassis where the backplane provides network and power, additional advantages and uses are also possible for at least some embodiments of the storage appliances and associated storage pods encompassed herein. In particular, it should be appreciated that, by applying power and network connectivity to the storage pods, along with software, the storage pods can be used in a manner in which the storage pods are modular storage devices that are fully capable of acting as API (application program interface or application programming interface) endpoints for application data storage. Additionally, it should also be appreciated that storage pods can be used anywhere power and network connectivity is available. As a result, at least some embodiments of storage appliances encompassed herein utilize one or more storage pods each having a different connection (terminal or port) on the back thereof to allow for the respective storage pod to be plugged into a Power-Over-Ethernet (PoE) port. With such a design, a single Ethernet cable can allow for each individual storage pod to be used anywhere such a port is available. Thus, storage can grow wherever a PoE port is available.

It should be appreciated that, although several embodiments of storage appliances and storage pods, and arrangements of storage appliances and storage pods in relation to other (e.g., external) devices, are described above, the present disclosure is intended to encompass numerous other embodiments in addition to or differing from those described above. For example, although the above disclosure describes the use of the Ceph software platform, in alternate embodiments other software can be employed such as the ZFS file system/local file manager designed by Sun Microsystems, Inc., formerly of Santa Clara, Calif., now part of Oracle Corp. of Redwood City, Calif. Additionally for example, although particular description is provided above regarding the nature and functioning of the first and second Ethernet ports 702 and 703, it should be understood that in other embodiments the ports can play different roles. For example, in some other embodiments, the first Ethernet port 702 associated with the management module 112 can allow for daisy-chained connection of the storage appliance with one or more other storage appliances.

Also, in other embodiments of storage appliances encompassed herein, any of a variety of different ports or terminals can be employed, and any arbitrary number of such ports or terminals can be employed, to allow for any of a variety of communications to occur in accordance with any of a variety of formats, protocols, and communication technologies (e.g., copper-based, optical, or wireless communications technologies) between storage appliances and other devices or systems such as (but not limited to) third-party computers. Further for example, in some additional embodiments in which the storage pods include PoE ports, each storage pod can take the form of a small box that stores data through an API using PoE, and many such boxes (storage pods) can be plugged in so as to extend the overall storage size or overall amount of storage capability.

Therefore, it is specifically intended that the present invention not be limited to the embodiments and illustrations contained herein, but include modified forms of those embodiments including portions of the embodiments and combinations of elements of different embodiments as come within the scope of the following claims.

We claim:

1. A modular software-defined storage system, the system comprising:
a backplane;
a plurality of first storage pods each configured to be at least indirectly coupled to the backplane, wherein each of the first storage pods includes a respective memory component and a respective processing component;
a management module coupled to the backplane, wherein the management module includes a non-transitory computer readable storage medium storing at least one computer program for causing the first storage pods to be configured for operation and for facilitating, when the first storage pods are configured for operation, first storage of first information on the first storage pods in accordance with a software-defined storage application;
a first interface coupled at least indirectly with the backplane or the management module by which an additional computer device can at least indirectly engage in communications with the storage system in a manner resulting in the first storage of the first information on the first storage pods; and
a second interface coupled at least indirectly with the backplane or the management module by which the storage system can at least indirectly engage in additional communications with an additional system having at least one additional storage pod such that the storage system is expanded to allow for additional storage of additional information on the at least one additional storage pod.

2. The storage system of claim 1,
wherein the software-defined storage application is a Ceph application, and
wherein the management module is configured to govern both the first storage of first information on the storage pods and also the additional storage of the additional information on the at least one additional storage pod.

3. The storage system of claim 2,
wherein the second interface allows for the storage system to provide an expandable amount of storage above that afforded by the storage pods, and
wherein the second interface includes an Ethernet switch that allows for the storage system to be coupled at least indirectly, in a daisy-chain configuration, with both the additional system and at least one further system having at least one further storage pod.

4. The storage system of claim 1,
wherein the first interface includes an Ethernet switch, and
wherein the management module is configured to provide interface signals that are at least indirectly output by the Ethernet switch that, upon being received by the additional computer device, allow for the providing of a web-based management interface by which information regarding health or operational characteristics of the storage system can be output and also by which commands concerning operations of the storage system can be received.

5. The storage system of claim 1, further comprising a power supply that is coupled to the backplane,
wherein the backplane is configured both to provide power to the first storage pods and to allow for networked communications of the first information with the first storage pods.

6. The storage system of claim 1, further comprising a plurality of visual indicators respectively associated with a plurality of positions along the storage system that are respectively proximate to respectively locations at which the respective first storage pods are positioned when installed in the storage system, and wherein the storage system is configured to cause the respective visual indicators to provide respective visual indications respectively indicative of respective health or operational status characteristics of the respective first storage pods.

7. The storage system of claim 6, further comprising at least one fan that serves to cool the storage system including the first storage pods,
wherein the respective operational status characteristics include at least one temperature status characteristic.

8. The storage system of claim 7, further comprising a status display that is configured to output an indication of a proportion of a total available storage capability of the storage system that is currently being utilized,
wherein the visual indicators are LED indicators and the status display is a touch screen display

9. The storage system of claim 1, wherein at least one of the storage pods includes a port that allows for the storage pod to be plugged into a Power-Over-Ethernet (PoE) port.

10. A storage pod for use as part of a modular software-defined storage system, the storage pod comprising:
a memory device including one or more of a hard drive, a solid state disk, a random access memory (RAM) device, and a Flash memory device;
a processing device coupled to the memory device, the processing device including one or more of a CPU component and a SOC component; and
a first port coupled at least indirectly to the processing device by which the storage pod can be electrically coupled to a backplane of the modular software-defined storage system,
wherein the processing device includes a non-transitory computer readable storage medium configured to be capable of storing at least one computer program for allowing the storage pod to receive and store first information at the memory device in accordance with a software-defined storage application, and
wherein the storage pod is configured to engage in communications with the backplane by way of the first port and also to receive power from the backplane by way of the first port.

11. The storage pod of claim 10, wherein an Ethernet switch associated with the processing device allows for a providing of one or more of a storage management interface, a storage data interface, and a storage replication interface.

12. The storage pod of claim 11, wherein the memory device includes each of the hard drive, the solid state disk, the RAM device, and the Flash memory device, and
wherein the hard drive is configured to perform a data storage function, the solid state disk is configured to provide a journal storage function, the RAM device is configured to provide a system memory function, and the Flash memory device is configured to perform an operating system (OS) storage function.

13. A method for providing modular software-defined storage, the method comprising:
providing a main structure having a backplane and a management module;
receiving at the backplane a first storage pod so that the first storage pod is electrically coupled to the backplane, wherein the first storage pod includes both a memory device and a processing device;
sending, from the processing device of the first storage pod to the management module, first information regarding a first characteristic of the first storage pod;
communicating, from the management module to the processing device of the first storage pod, at least some second information so as to achieve configuration of the first storage pod for operation as part of a storage system including the first storage pod and the main structure,
wherein the second information includes at least some computer programming configured to allow the storage pod to receive and store third information at the memory device of the first storage pod in accordance with a software-defined storage application; and
operating the management module, the backplane, and the first storage pod as a storage system so that the third information is stored at the memory device of the first storage pod as governed by the management module in accordance with the software-defined storage application.

14. The method of claim 13, further comprising:
after the receiving of the first storage pod at the backplane, causing the first storage pod to receive power;
after the sending of the first information regarding the first characteristic, determining whether a database accessible by the management module has stored therewithin additional information corresponding to the first storage pod; and
if the database has stored therewithin the additional information, then sending a code for use by the first storage pod for establishing a configuration connection.

15. The method of claim 14, further comprising:
further providing a DHCP request for receipt by the management module;
determining at the management module whether a module MAC address is present;
further sending a reply with either a static IP address or a dynamic IP address from the management module to the first storage pod;
experiencing a TFTP booting operation at the first storage pod;
commencing operation of a Python agent at the first storage pod; and
subsequent to the sending of the code, determining whether the storage pod should serve a monitoring role.

16. The method of claim 13, further comprising:
further operating the management module, the backplane, and the first storage pod so that the third information is retrieved from the memory device of the first storage pod and provided to the backplane, wherein the software-defined storage application is a Ceph application.

17. The method of claim 16, further comprising:
receiving the third information and a command to store the third information from a computer system coupled at least indirectly to the storage system by way of an Ethernet switch associated with the management module,
wherein a location at which the third information is stored on the first storage pod is determined by the management module operating in accordance with the software-defined storage application.

18. The method of claim 13, further comprising:
additionally communicating fourth information regarding a health or operational status characteristic of the first storage module to a computer system coupled at least indirectly to the storage system by way of an Ethernet switch associated with the management module, or
displaying, by way of at least one visual indicator or a status display provided on a housing encasing the backplane and coupled at least indirectly to the backplane, an indication of the fourth information regarding the health or operational status characteristic.

19. The method of claim 13, further comprising:
receiving at the backplane a second storage pod so that the second storage pod is electrically coupled to the backplane;
additionally sending further information regarding a second storage pod characteristic to the management module;
additionally communicating, from the management module to the second storage pod, at least some further information so as to achieve configuration of the second storage pod for operation as part of the storage system; and
additionally operating the second storage pod as part of the storage system so that at least some additional information is stored at a second memory device of the second storage pod as governed by the management module in accordance with the software-defined storage application.

20. The method of claim 19, further comprising:
expanding an overall storage capacity of the storage system to include an additional amount of storage capacity provided by a third storage pod that cannot be fit within a predefined number of slots of a housing of the storage system, by linking an additional storage device including the third storage pod to the storage system by way of a port of the storage system, and
additionally operating the third storage pod so that at least some further information is stored at the third storage pod, as governed by the management module in accordance with the software-defined storage application.
